(19) United States
(12) Patent Application Publication
(10) Pub. No.: US 2006/0132218 A1
(43) Pub. Date: Jun. 22, 2006

(54) Body biasing methods and circuits

(76) Inventors: James W. Tschanz, Portland, OR (US); Siva G. Narendra, Portland, OR (US); Vivek K. De, Beaverton, OR (US)

Correspondence Address: BLAKELY SOKOLOFF TAYLOR & ZAFMAN, 12400 WILSHIRE BOULEVARD, SEVENTH FLOOR, LOS ANGELES, CA, 90025-1030, US

(21) Appl. No.: 11/018,016

(22) Filed: Dec. 20, 2004

(51) Int. Cl. H03K 3/01

(52) U.S. Cl. 327/534

(57) ABSTRACT

In some embodiments, a chip is provided that comprises a group of transistors and a body bias generator. The group of transistors is coupled to the body bias generator. The body bias generator is configured to body bias the transistors at a level based on one or more measured parameters associated with the chip and on an operating mode. Other embodiments are disclosed herein and/or are otherwise claimed.

### TECHNICAL FIELD

Embodiments disclosed herein relate generally to integrated circuit (“IC”) devices and in particular to transistor body biasing circuits and schemes.

### BACKGROUND

Performance and power are typically considered when designing integrated circuit (“IC”) chips such as microprocessors and microcontrollers. (As used herein, the term “chip” (or die) refers to a piece of a material, such as a semiconductor material, that includes a circuit such as an integrated circuit or a part of an integrated circuit.) For example, with portable devices such as laptop computers, cellular telephones, and personal digital assistants (“PDA”s), reducing power consumption may be considered since such devices are typically powered by batteries whose charge times generally depend on the average power consumption of the processor. In other components such as servers and network components, power reduction may also be a concern, e.g., to satisfy thermal criteria. Hence, various power reduction techniques such as clock gating and the use of power-down states have been developed to reduce power consumption.

At the same time, however, performance (as measured by capable operating frequency) is another factor that may be considered and has traditionally cut against reducing power consumption. One of the limiters to performance is the variation in physical parameters of a wafer, generally from lot to lot), which result in variations in operating parameters such as leakage and transistor threshold voltage. This can cause processors of a given design to run more slowly than others of the same design, while others may be faster but consume more power. Because of these process variations, after fabrication, chips are typically “binned” (or sorted) based on their operating frequency capabilities into different frequency bins (or groups). Typically, higher-frequency devices are more valuable, so it is desirous to have more devices in the higher frequency groups.

Transistor body biasing is a technique that can affect the operational parameters of transistors. In conventional approaches, body biasing has been used to either reduce power consumption or to improve the operating frequency of a processor. For example, to reduce average power consumption, some approaches have used reverse body biasing to reduce leakage currents during standby (or otherwise less active) modes. On the other hand, in order to improve frequency response, other approaches, after die fabrication and frequency capability classification, have used a forward body bias to improve the frequency response of a device in order to “move” the device into a higher frequency category. Presented in this disclosure are different embodiments that combine concepts of one or both of these approaches.

### BRIEF DESCRIPTION OF THE DRAWINGS

Embodiments of the invention are illustrated by way of example, and not by way of limitation, in the figures of the accompanying drawings in which like reference numerals refer to similar elements.

FIG. 1 is a schematic block diagram of a body biasing circuit in accordance with some embodiments of the present invention.

FIG. 2 is a timing diagram showing relative power, frequency, and body biasing operational levels in accordance with some embodiments of the present invention for the body bias circuit of FIG. 1.

FIG. 3 is a block diagram of a system having a processor chip with body biasing in accordance with some embodiments of the present invention.

### DETAILED DESCRIPTION

Body biasing can be applied to N-type metal oxide-semiconductor (“NMOS”) transistors and P-type MOS (“PMOS”) transistors to adjust their threshold voltage levels (V_{T}). A body bias is a voltage applied, or caused to be applied, between the body and source of a transistor such as a MOS device. A forward body bias will generally lower the magnitude of a transistor's threshold voltage (|V_{T}|), while a reverse body bias will generally increase it. (Note that the terms: “threshold voltage” or “threshold voltage level” refer to the absolute value or magnitude, |V_{T}|, of a threshold voltage) An NMOS transistor is forward body biased when its body to source voltage (V_{BS}) is positive, while a PMOS transistor is forward body biased when its source to body voltage (V_{SB}) is positive. On the other hand, an NMOS device is reverse biased when its body to source voltage is biased at a negative level (V_{BS}<0), whereas a PMOS transistor is reverse biased when its source to body is at a negative level (V_{SB}<0).

Since it decreases a transistor's threshold voltage, a forward body bias can be used to improve the transistor's frequency response. Alternatively, by raising a transistor's threshold voltage level, a reverse body bias can be used to reduce leakage currents and thereby reduce average power consumption. With different embodiments disclosed herein, transistor threshold levels for one or more groups of transistors are adjusted (raised, lowered, or kept the same) depending upon the operating mode associated with the transistor group. For example, during more active modes, threshold levels are decreased to enhance frequency response but in less active modes (e.g., during a so-called “sleep” mode), threshold levels can be raised to reduce power consumption when higher frequency performance is not otherwise needed. In some embodiments, the amount of threshold level adjustment can be based not only on the transistor group's operating mode, but also, on its measured (either directly or indirectly) unbiased threshold levels to compensate for process variations. That is, body bias threshold level adjustment can also be used to compensate for operating parameter variations occurring from die to die, wafer to wafer, or more significantly, from wafer lot to wafer lot.

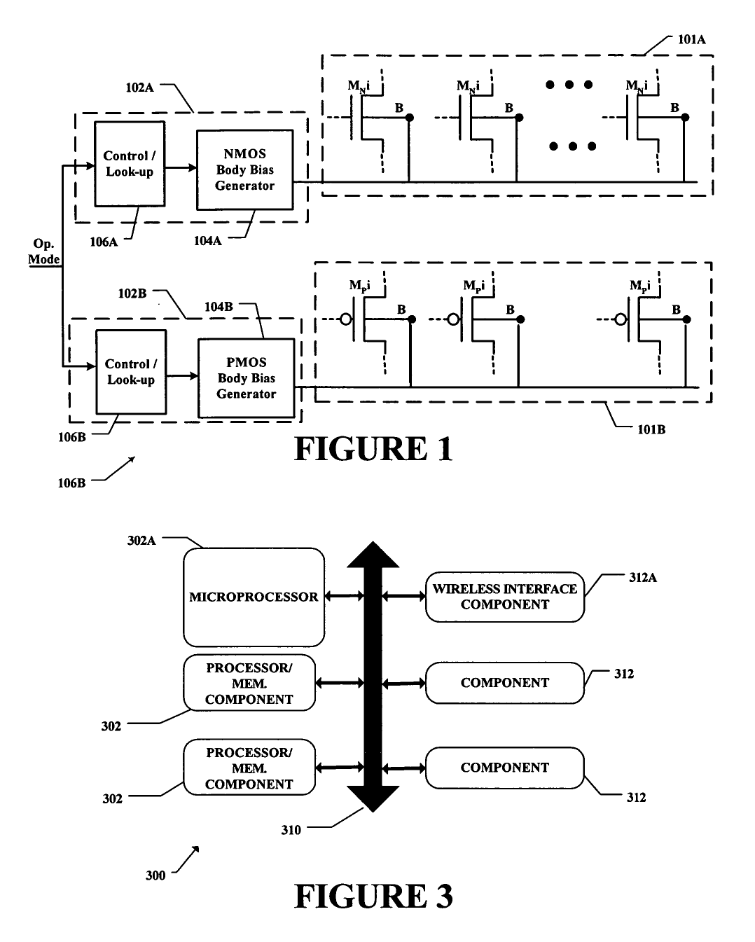

FIG. 1 shows one embodiment of a circuit 100 for biasing one or more groups of transistors in a chip such as a processor chip. In this depiction, transistor groups 101A, 101B are biased with body bias circuits 102A, 102B, respectively. Body bias circuit 102A comprises an NMOS body bias generator 104A and a control/look-up circuit 106A. Similarly, body bias circuit 102B comprises a PMOS body bias generator 104A and a control/look-up circuit 106A. The two body bias circuits, 102A, 102B are similar except that, as indicated, circuit 102A biases a group of NMOS transistors (M_{N}(i)), while circuit 102B biases a group of PMOS transistors (M_{P}(i)). (It should be appreciated that other body biasing embodiments may include only one transistor group or multiple groups.)

In each body bias circuit 102A/B, the body bias generator 104A/B is coupled to the bodies (B) of the transistors for its transistor group 101 A/B to bias them at a suitable voltage (or voltage level). Each body bias generator 104A/B is also coupled to a control/look-up circuit 106A/B. The control/look-up circuit 106A/B receives at an input an operating mode signal (labeled as “Op.Mode” in the drawing). Based on information provided by this signal, it controls its associated body bias generator to produce a suitable body bias voltage. (In the depicted embodiment, the operating mode signal indicates the mode in which the transistor group is currently operating. For example, the transistor groups could be part of a processor chip operating in one of several different power management modes of activity, e.g., active, less active, sleep, etc. Pursuant to an appropriate power management scheme, in some embodiments, responsive to the operating mode signal, the generators bias the bodies for increased frequency response during the more active modes and for reduced current leakage during the less active modes.)

Before discussing more about the body bias circuit components, the transistor groups 101A/B will now be addressed. As used herein, the term “transistor group” refers to a group, of any size or type, of transistors on a die whose bodies are to be biased by a common body bias generator. They could consist of only one or several transistors, or they could consist of thousands or millions of transistors depending on the concerns of a given design. Along these lines, while they could, their constituent transistors need not have a functional or geographical relation to one another. However, because they are “grouped” so that their bodies can be biased by a common body bias generator, they will usually share a common body or their bodies will typically otherwise be coupled to one another.

The depicted transistor group 101A comprises a plurality of NMOS transistors (M_{N}(i). As indicated, their bodies (B) are coupled to the body bias generator 104A to receive a body bias voltage. Note that their gates, sources, and drains are not shown coupled to another device or node because this group could include NMOS transistors from anywhere in the chip. While many of the NMOS transistors may have their sources grounded, others could be differently configured, e.g., as part of a logic stack. Even though their bodies would not be biased the same as those with source to ground connections, their operations could still be enhanced, albeit to a different extent.

In this embodiment, the chip is formed with a P-type substrate. The depicted group of transistors are formed on this substrate, which serves as a common body for the transistors. (It should be recognized, however, that in other embodiments, they could constitute NMOS transistors sharing a well that serves as a common body, e.g., P-well in an N-well on a P-type substrate or P-well on an N-type substrate.) In the depicted embodiment, the NMOS transistor group 101A includes most or all of the NMOS transistors formed on the chip's P-type substrate. Because this involves many transistors spread over a relatively wide area, a conductor grid may be suitably coupled to the substrate to effectively disseminate the body bias voltage evenly throughout the substrate (or body). Note that by biasing such a large group of transistors, the chips frequency response and power reduction characteristics can be greatly enhanced.

The depicted transistor group 101B comprises a plurality of PMOS transistors (M_{P}(i)). As indicated, their bodies (B) are coupled to the body bias generator 104B to receive a body bias voltage. Note that their gates, sources, and drains are not shown coupled to another device or node because this group could include PMOS transistors from anywhere in the chip. While many PMOS transistors may have their sources coupled to a supply voltage (V_{cc}), others could be differently configured, e.g., as an interposed device in a stack. Even though their bodies would not be biased the same as those with source to V_{cc} connections, their operations could still be enhanced, albeit to a different extent.

In the depicted embodiment, the transistors (M_{P}(i)) are formed in a common N-type well formed in the chip's P-type substrate. (It should be recognized, however, that they alternatively could be formed on a common substrate or in a well within a well within a substrate.) In this embodiment, they correspond to a group of P type transistors, formed in a common well, that perform a related function. Because they share a common function, they can be biased not only to enhance their performance and reduce power consumption during appropriate operating modes, but also, they can be biased in connection with their functionality to have a relatively higher frequency response, if needed, or to have increased power reduction, if tolerable, in view of the particular function they are performing.

Returning to the body bias circuits 102A/B, a body bias generator 104A/B may be formed from any suitable combination of circuit devices to generate an appropriate body bias voltage for its associated transistor group. For example, it could comprise a digital-to-analog (“D/A”) converter with an appropriate output voltage swing. That is, depending upon whether the body bias generator is called on to provide a reverse body bias to its transistor group, it may have an output swing extending below ground, above Vcc, or both. For example, with NMOS transistors having their sources coupled to ground, if reverse biasing pursuant to an implemented body biasing scheme is required, the body bias generator should include a negative output voltage capability. On the other hand, with PMOS transistors having their sources coupled to V_{cc}, if reversed biasing is required, the body bias generator should include an output voltage capability that can exceed V_{cc}. With either of these cases, as persons of skill will recognize, negative voltages and voltages in excess of Vcc could, for example, be achieved with a D/A converter having one or more appropriately configured charge pump circuits to provide voltages outside of a ground-to-V_{cc} swing.

In the depicted embodiment, both forward and reverse biasing may be employed. Body bias generator 104A comprises a D/A converter with a negative (as well as a positive) output voltage capability for both forward and reverse body biasing transistor group 101A. (Note, that as addressed below, both positive and negative voltage output capability is not necessarily required to achieve both forward and reverse body biasing.) Body bias generator 104B comprises a D/A converter with an output capable of generating a positive voltage in excess of V_{cc} thereby allowing it to both forward and reverse body bias transistor group 101B. When operated, each generator 104A/B receives a digital value from its associated control/look-up circuit 106A/B and outputs a body bias voltage corresponding to this value.

A control/look-up circuit may be any suitable circuit for receiving an operating mode signal and generating (for a body bias generator) a signal to cause the body bias generator to generate a suitable body bias voltage. In the depicted embodiment, it comprises control circuitry (including decoding circuitry) and a one-time-programmable (“OTP”) look-up table. The look-up table could be formed from any suitable circuitry such as a programmable fuse array. After a chip has been fabricated (and its relevant process-varying parameter(s) are measured or otherwise obtained—either directly or indirectly by way of a sample in its lot), appropriate body bias voltage values are programmed in the look-up table for each operating mode. The control circuitry is configured to couple an appropriate value from the look-up table to the body bias generator based on the value of the input operating mode signal. That is, the operating mode signal causes an appropriate body bias value to be addressed and coupled through to the body bias generator. (It should be appreciated that various other control/look-up schemes could be used. for example, instead of programming a separate bias voltage value in the look-up table for each operating mode, it could simply include an offset or multiplier value to be used by the control circuitry to otherwise generate a suitable body bias value.)

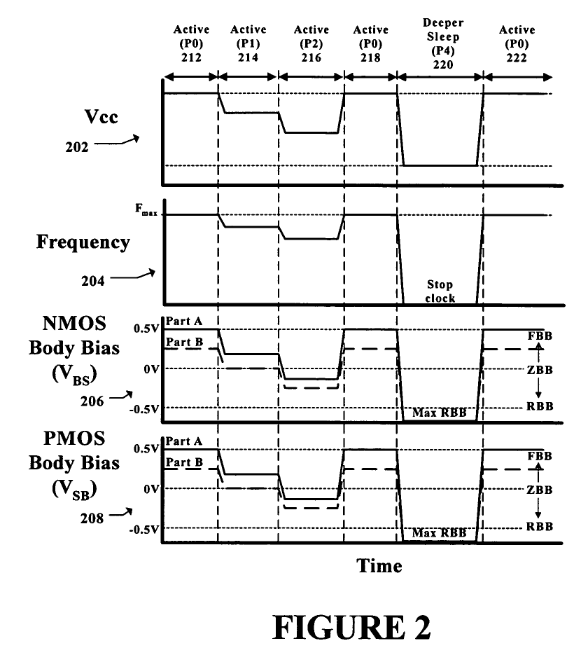

With reference to FIG. 2, one embodiment of a body-biasing scheme is graphically illustrated for the body bias circuit of FIG. 1. The graph shows V_{cc} (202), frequency (204), NMOS body bias (206), and PMOS body bias (208) levels as a function of operating mode over different periods of time (212 through 222). In this embodiment, the V_{cc} (202) graph portion represents a supply voltage powering the biased transistors, and the frequency graph portion (204) indicates the relative maximum frequency for data and control signals driving the biased transistors. The NMOS body bias graph portion 206 corresponds to a body bias voltage applied to the NMOS transistor group 101A, wile the NMOS body bias graph portion 208 corresponds to a body bias voltage applied to the NMOS transistor group 101B. In this embodiment, so-called “SpeedStep” (or “Geyserville”) technology power management scheme is used for the chip (e.g., processor chip). As indicated in the graph, different operational modes of activity ranging from P0 (most active) to P4 (least active) are used and shown for the different time periods (212 through 222).

As indicated in the graph, the Vcc and the frequency are changed dynamically to save power. In the P0 (most active) mode, the chip (or at least a relevant transistor group) is operated at maximum V_{cc} and maximum frequency, while in the various other modes, it is operated at reduced V_{cc} and frequency. During the so-called “Deeper Sleep” mode (P4), the supply voltage is reduced to its minimum allowed value, and the frequency is shut off for maximum power reduction.

In cooperation with these Vcc and frequency levels, as shown in the graph, the NMOS and PMOS body biases are modulated in the following manner. During the most active (P0) mode, a suitable, maximum amount of forward body bias is applied, as determined by design criteria in connection with measured, post-fabrication chip parameters. (Note that as indicated, different chips (“Part A” and “Part B”) may have different amounts of bias applied due to fabrication process variations.) When the frequency and voltage are changed, the body biases are also changed to optimize the power reduction. As they go down, the transistor bodies are less forwardly biased or are reverse biased. As is depicted in the graph, when the deeper sleep mode (P4) is entered and the clock (or other relevant frequency generator) is shut off, the maximum amount of reverse bias is applied for maximum leakage reduction

Note that in the depicted scheme of FIG. 2, the NMOS (206) and PMOS (208) bias levels are the same. In alternative embodiments, however, they may (and many times will) be biased at different levels as a result of differing physical parameters and device functionality for different types of transistors within different transistor groups.

In addition, while both forward and negative biasing is used in the depicted example, it should be appreciated that alternative embodiments could use only forward or reverse biasing and still achieve both frequency performance enhancement and power reduction as with the depicted embodiment. For example, in some embodiments, the transistors in a transistor group could be processed to have relatively high or relatively low unbiased voltage threshold levels. that is, they could be “shifted” upward or downward. with an up-shifted threshold level, a nominal forward body bias could be used to move the threshold level down to an otherwise normal level, higher forward biases could be used to move the threshold level down even further to enhance frequency response, and lesser (or zero) forward biases could be used to move it above the nominal level to reduce power consumption during the less active modes. (The same but opposite approach could be implemented using only reverse body biasing with transistors having downward shifted threshold voltage levels.) One benefit of such an approach is that a body bias generator capable of generating only positive voltages ranging between ground and V_{cc} could be employed.

On the other hand, in some embodiments, using both forward and reverse biasing may provide better flexibility in achieving optimal frequency performance enhancement and power reduction. For example, in some embodiments, a transistor group's aggregate threshold level is shifted upward in the fabrication process from what it otherwise would be for a given chip design. Different forward biasing levels can then be used to achieve optimal frequency response characteristics for different active operating states. Reverse biasing is used during the least active mode(s) to achieve a significant reduction in power consumption. One benefit of this approach is that junction leakage, which is more problematic with higher supply voltages and reverse body biasing, is mitigated since reverse biasing is employed when the supply voltage is reduced. At the same time drain-induced barrier lowering (“DIBL”) can be reduced so that the degradation of short channel effects due to reverse body bias is not as significant.

With reference to FIG. 3, one example of a system (system 300 for a computer) that may be implemented with one or more IC chips or modules (including a microprocessor chip 302A) is shown. System 300 generally comprises one or more processor/memory components 302, an interface system 310, and one or more other components 312. At least one of the one or more processor/memory components 302 is communicatively linked to at least one of the one or more other components 312 through the interface system 310, which comprises one or more interconnects and/or interconnect devices including point-to-point connections, shared bus connections, and/or combinations of the same.

A processor/memory component is a component such as a processor, controller, memory array, or combinations of the same contained in a chip or in several chips mounted to the interface system or in a module or circuit board coupled to the interface system. Included within the depicted processor/memory components is microprocessor chip 302A, which has one or more transistor groups body biased in accordance with an embodiment of the invention, as disclosed herein. The one or more depicted other components 312 could include any component of use in a computer system such as a sound card, network card, Super I/O chip, or the like. In the depicted embodiment, the other components 312 include a wireless interface component 312A, which serves to establish a wireless link between the microprocessor 302A and another device such as a wireless network interface device or a computer. It should be noted that the system 300 could be implemented in different forms. That is, it could be implemented in a single chip module, a circuit board, or a chassis having multiple circuit boards. Similarly, it could constitute one or more complete computers or alternatively, it could constitute a component useful within a computing system.

While the inventive disclosure has been described in terms of several embodiments, those skilled in the art will recognize that the invention is not limited to the embodiments described, but can be practiced with modification and alteration within the spirit and scope of the appended claims. For example, while the body biasing embodiments are primarily discussed for transistor groups in processor chips, other types of chips (such as bus, transceiver, network, or any other chips that have circuits driven at high frequencies) could also employ body biased transistor groups as discussed herein.

It should be appreciated that example sizes/models/values/ranges may have been given, although the present invention is not limited to the same. As manufacturing techniques (e.g., photolithography) mature over time, it is expected that devices of smaller size could be manufactured. In addition, well known power/ground connections to IC chips and other components may or may not be shown within the FIGS. for simplicity of illustration and discussion, and so as not to obscure the invention. Further, arrangements may be shown in block diagram form in order to avoid obscuring the invention, and also in view of the fact that specifics with respect to implementation of such block diagram arrangements are highly dependent upon the platform within which the present invention is to be implemented, i.e., such specifics should be well within purview of one skilled in the art. Where specific details (e.g., circuits) are set forth in order to describe example embodiments of the invention, it should be apparent to one skilled in the art that the invention can be practiced without, or with variation of, these specific details. The description is thus to be regarded as illustrative instead of limiting.

What is claimed is:

1. A chip, comprising:
(a) a group of transistors; and
(b) a body bias generator coupled to the group of transistors, said generator to body bias the transistors at a level based on one or more measured parameters associated with the chip and on an operating mode.

2. The chip of claim 1, in which the one or more measured parameters comprises transistor threshold voltage.

3. The chip of claim 2, in which the bodies are biased to decrease the transistors' threshold voltage levels during more active modes and raise them during less active modes.

4. The chip of claim 3, in which the transistor bodies are less forwardly biased during the less active modes and more forwardly biased during the more active modes.

5. The chip of claim 3, in which the body bias generator is capable of generating both positive and negative bias voltage levels, wherein the bodies are forwardly biased during a most active mode and reverse biased during a least active mode.

6. The chip of claim 1, in which the group of transistors are NMOS transistors with their bodies formed from a common substrate.

7. The chip of claim 1, in which the body bias generator provides a maximum forward bias voltage that is based on the one or more measured parameters.

8. The chip of claim 1, further comprising a look-up table circuit coupled to the body bias generator when the chip is being operated, said look-up table providing body bias level information responsive to the chip's operating mode.

9. The chip of claim 1, in which the one or more measured parameters comprises leakage current.

10. The chip of claim 1, in which the group of transistors comprises a group of common-welled PMOS transistors.

11. The chip of claim 1, in which the one or more measured parameters associated with the chip are obtained from measurements of another representative chip from the same chip lot.

12. A device comprising:
(a) a group of transistors; and
(b) a body bias generator coupled to the transistors , the body bias generator to body bias the transistors to lower their voltage threshold levels during one or more active modes and to raise their voltage threshold levels during one or more less active modes.

13. The device of claim 12, in which the body bias generator comprises a D/A converter that is capable of both forward and reverse biasing the group of transistors.

14. The device of claim 13, in which the D/A converter is capable of biasing the group of transistors with both positive and negative voltages

15. The device of claim 13, in which the D/A converter is capable of biasing the group of transistors with voltages above and below a supply voltage that is used to power the transistor group.

16. The device of claim 12, further comprising a control/look-up circuit to provide to the body bias generator a signal for controlling the body bias generator to generate a body bias voltage based on a received operating mode signal.

17. The device of claim 12, in which the body bias generator is configured to body bias the transistors to lower their voltage threshold levels based on measured operating parameters associated with the transistors.

18. The device of claim 17, in which the measured operating parameters comprise threshold voltage.

19. A method, comprising:
(a) at least indirectly measuring a threshold level associated with a transistor group in a fabricated chip; and
(b) programming a body bias circuit that is part of the chip to body bias the transistors (i) to have increased frequency response in view of the measured threshold level during a most active mode, and (ii) to have reduced current leakage during a least active mode.

20. The method of claim 19, in which the transistors are fabricated to have sufficiently high threshold voltage levels such that the transistors can be forward body biased for both the least and most active modes.

21. The method of claim 20, in which the measured threshold level is an aggregate level for the transistor group.

22. The method of claim 19, in which the body bias generator can provide both a positive and negative voltage.

23. A system, comprising:
(a) a microprocessor having:
(i) a group of transistors each having a body, and
(ii) a body bias generator coupled to the transistor bodies, said generator being configured to bias the bodies at a level based on one or more measured parameters associated with the chip and on an operating mode; and
(b) a wireless interface component communicatively linked to the microprocessor.

24. The system of claim 23, in which the body bias generator comprises a D/A converter that is capable of providing both positive an negative bias voltages.

25. The system of claim 23, in which the transistors are biased, based on the measured parameters, at a level that enhances their unbiased frequency responses during a most active operating mode.
